(19) United States
(12) Patent Application Publication
(10) Pub. No.: US 2019/0287956 A1
(43) Pub. Date: Sep. 19, 2019

(54) RECESSED SEMICONDUCTOR DIE IN A DIE STACK TO ACCOMODATE A COMPONENT

(71) Applicant: Intel Corporation, Santa Clara, CA (US)

(72) Inventors: Digvijay A. Raorane, Chandler, AZ (US); Ravindranath V. Mahajan, Chandler, AZ (US)

(73) Assignee: Intel Corporation, Santa Clara, CA (US)

(21) Appl. No.: 16/464,665

(22) PCT Filed: Dec. 30, 2016
(86) PCT No.: PCT/US16/69502

§ 371 Date: May 28, 2019

(51) Int. Cl. H01L 25/18; H01L 23/31; H01L 23/48; H01L 23/522; H01L 21/56; H01L 21/768

(52) U.S. Cl. CPC H01L 25/18; H01L 23/3185; H01L 23/481; H01L 24/09; H01L 21/565; H01L 21/76898; H01L 23/5226

(57) ABSTRACT

An apparatus is provided comprising: a substrate; a die having a first side and a second side, wherein the die is mounted on the substrate such that the first side of the die faces the substrate, and wherein at least a portion of the first side of the die is removed to form a recess in the die; and a component, wherein at least a part of the component is disposed within the recess in the first die.

### BACKGROUND

Modern consumer electronic devices, e.g., cell phones, smart phones, tablets, laptops, etc., are becoming thinner. Semiconductor packages included in these devices often need components that are to be mounted on a substrate of the packages. In a semiconductor package, these components, for example, can increase a height of the package, and/or can increase a foot print of the package.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-sectional view of a semiconductor package comprising a stacked plurality of dies, wherein a first die of the stacked plurality of dies is selectively recessed to accommodate a component in a recessed region in the first die, according to some embodiments.

FIGS. 2A-2G illustrate a process of forming a semiconductor package, where the semiconductor package comprises a recessed region in a die in which a component is mounted, according to some embodiments.

FIGS. 3A-3D illustrate another process of forming a semiconductor package, where the semiconductor package comprises a recessed region in a die in which a component is mounted, according to some embodiments.

FIG. 4 illustrates a cross-sectional view of a semiconductor package comprising a stacked plurality of dies, wherein a first die of the stacked plurality of dies and a substrate is selectively recessed to accommodate a component, according to some embodiments.

FIG. 5A illustrates a cross-sectional view of a semiconductor package comprising a stacked plurality of dies, wherein a first die of the stacked plurality of dies is selectively recessed to accommodate a component that is electrically coupled to the first die, according to some embodiments.

FIG. 5B illustrates a cross-sectional view of a semiconductor package comprising a stacked plurality of dies, wherein a first die of the stacked plurality of dies and a substrate are selectively recessed to accommodate a component that is electrically coupled to the first die, according to some embodiments.

FIG. 6 illustrates a cross-sectional view of a semiconductor package comprising a stacked plurality of dies, wherein a first die of the stacked plurality of dies is selectively recessed to accommodate a component that is electrically coupled to the first die and to a substrate, according to some embodiments.

FIG. 7A illustrates a cross-sectional view of a semiconductor package comprising a stacked plurality of dies, wherein a first die of the stacked plurality of dies is selectively recessed to accommodate a first component, and wherein a second component is disposed between an un-recessed region of the first die and the substrate, according to some embodiments.

FIG. 7B illustrates a cross-sectional view of a semiconductor package comprising a stacked plurality of dies, wherein a first die of the stacked plurality of dies is selectively recessed to accommodate a first component, and wherein a second component is disposed between an un-recessed region of the first die and the substrate and attached to the substrate, according to some embodiments.

FIG. 8 illustrates a flowchart depicting a method for disposing a component in a recessed region of a die, where the die is part of a stack of multiple dies, according to some embodiments.

FIG. 9 illustrates a computing device, a smart device, a computing device or a computer system or a SoC (System-on-Chip), in which a second die is stacked on a first die in a flip chip configuration, where an inactive side of the first die is recessed and a component is disposed at least in part on the recessed region in the first die, according to some embodiments.

### DETAILED DESCRIPTION

In some embodiments, a semiconductor package may include a number of stacked dies. For example, a first die can be mounted on a substrate, and one or more additional dies can be mounted on the first die. In some embodiments, an inactive side of the first side can face the substrate, while the one or more additional dies can be mounted on an active side of the first die. Because the first die acts as an interposer between the one or more additional dies and the substrate, the first die is also sometimes referred to as an interposer die, or a silicon interposer.

In some embodiments, a component is to be mounted on a surface of the substrate, where the component is also sometimes referred to as a surface mount technology (SMT) component. The component can be any appropriate active or passive component, e.g., a capacitor, a resister, an inductor, a magnetic core inductor (MCI), a clock generation circuit, a voltage regulation circuit, a die, or the like.

In some embodiments, a section of the inactive side of the first die in the semiconductor package is removed or cut to form a recessed region in the first die. In some embodiments, the component is mounted on the substrate such that at least a part of the component is within the recessed region. In some other embodiments, the component is mounted on the first die such that at least a part of the component is within the recessed region.

There are many technical effects of the various embodiments. For example, the techniques described herein can be used to mount a second die on a first die, mount the first die on a substrate, create a recessed region in the first die, and dispose a component at least in part within the recessed region. Accordingly, a height of the semiconductor package is not increased due to the mounting of the component in the semiconductor package. A surface area or a footprint of the semiconductor package is also not increased due to the mounting of the component in the semiconductor package. Furthermore, the principles of this disclosure may also be used to include more than one such component (e.g., more than one SMT component) within a semiconductor package. Other technical effects will be evident from the various embodiments and figures.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.” The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

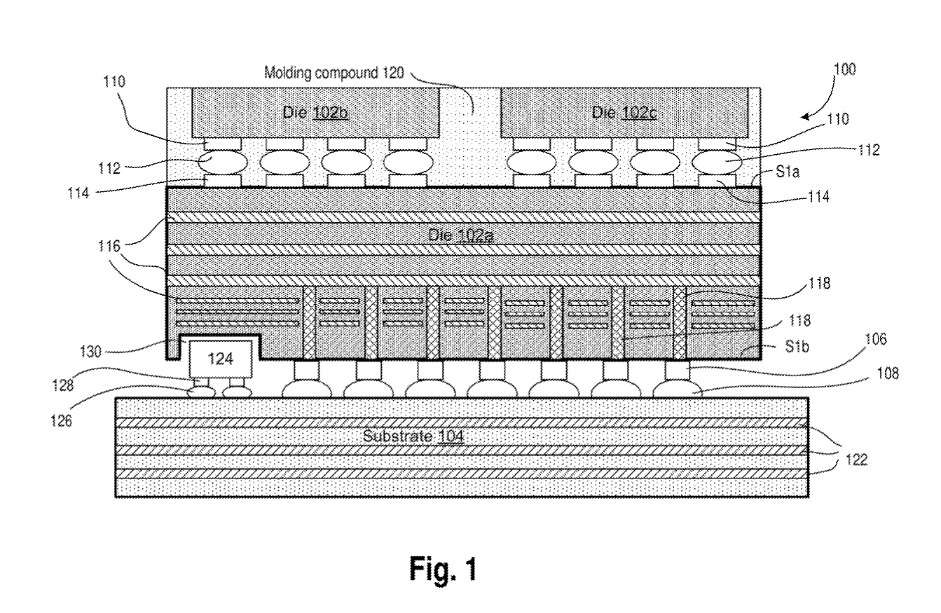

FIG. 1 illustrates a cross-sectional view of a semiconductor package 100 (henceforth also referred to as “package 100”) comprising a stacked plurality of dies (e.g., dies 102a, 102b, 102c), wherein a first die (e.g., the die 102a) of the stacked plurality of dies is selectively recessed to accommodate a component 124, according to some embodiments. In some embodiments, the stacked plurality of dies comprises the first die 102a, upon which a second die 102b and a third die 102c are stacked. Although in the example of FIG. 1 two dies 102b and 102c are stacked on the die 102a, any other number of dies can be stacked on the die 102a in any appropriate configuration. Merely as an example, one more dies can be stacked on one or both of the dies 102b and 102c. In another example, only a single die 102b can be stacked on the die 102a. In yet another example, three or more dies (e.g., the dies 102b, 102c, and another one or more dies) can be stacked in a side-by-side configuration on the die 102a.

In some embodiments, the dies 102a, 102b, and 102c can be any appropriate integrated circuit dies. For example, individual one of the dies 102a, 102b, 102c can be a processor, a system on a chip (SOC), a memory, an application specific circuit (ASIC), a modem, a baseband processor, a RF (radio frequency) IC, some combination of such functions, and/or the like. In some embodiments, one or more top dies of the package 100 (e.g., one or both the dies 102b or 102c) can be memory dies, while the bottom die 102a can be a processor.

A top surface and a bottom surface of the die 102a are labeled respectively as S1a and S1b in FIG. 1. The die 102a, for example, forms a bottom die in the package 100, and the dies 102b and 102c are configured to be stacked on the top surface S1a of the die 102a.

In some embodiments, the die 102a may be mounted on a substrate 104. In some embodiments, the substrate 104 may be a Printed Circuit Board (PCB) composed of an electrically insulating material such as an epoxy laminate. For example, the substrate 104 may include electrically insulating layers composed of materials such as, phenolic cotton paper materials (e.g., FR-1), cotton paper and epoxy materials (e.g., FR-3), woven glass materials that are laminated together using an epoxy resin (FR-4), glass/paper with epoxy resin (e.g., CEM-1), glass composite with epoxy resin, woven glass cloth with polytetrafluoroethylene (e.g., PTFE CCL), or other polytetrafluoroethylene-based prepreg material.

In some embodiments, the bottom surface S1b of the die 102a is attached to the substrate 104 via, for example, a plurality of interconnect structures 106 and 108. The interconnect structures 106, for example, are bumps, bump pads, metal pillars (e.g., copper pillars), balls formed using metals, alloys, solderable material, or the like. The interconnect structures 108, for example, are solder formed using metals, alloys, solderable material, or the like.

In some embodiments, the dies 102b and 102c are mounted on the top surface S1a of the die 102a via, for example, interconnect structures 110, 112, and 114. The interconnect structures 110, for example, are bumps, bump pads, metal pillars (e.g., copper pillars), balls formed using metals, alloys, solderable material, or the like, which are formed on a bottom surface of the dies 102b and 102c. The interconnect structures 114, for example, are bumps, bump pads, metal pillars (e.g., copper pillars), balls formed using metals, alloys, solderable material, or the like, which are formed on the top surface of the die 102. The interconnect structures 112, for example, are attachment components such as solder formed using metals, alloys, solderable material, or the like, which attaches the interconnect structures 110 and 114, as illustrated in FIG. 1.

In some embodiments, the interconnect structures 110, 112, and 114 are also referred to as a first level interconnect (FLI), e.g., because these interconnect structures form a first level of interconnects through which the dies 102b, 102c are connected to the substrate 104 via the die 102a. In some embodiments, the interconnect structures 106 and 108 are also referred to as a second level interconnect (SLI), e.g., because these interconnect structures form a second level of interconnects through which the dies 102a, 102b, 102c are connected to the substrate 104.

Various figures in this disclosure illustrate interconnect structures using which two elements of a semiconductor package are connected, and the interconnect structures are, for example, bumps, bump pads, metal pillars (e.g., copper pillars), balls formed using metals, alloys, solderable material, solder formed using metals, alloys, solderable material, and/or the like. However, in other embodiments and although not illustrated in any of the figures, in any of the semiconductor packages discussed in this disclosure, two elements can be attached, mounted, stacked or coupled by other appropriate manners, e.g., using anisotropic conductive films (ACF), anisotropic conductive pastes (ACP), and/or any adhesive based interconnect.

In some embodiments, the interconnect structures 110 of the die 102b are arranged in a ball grid array (BGA). Similarly, in some embodiments, the interconnect structures 110 of the die 102c are arranged in the BGA. Also, in some embodiments, the interconnect structures 106 of the die 102a are arranged in a BGA.

The dies 102b and 102c are mounted or stacked on the die 102a in, for example, a flip-chip configuration. In some embodiments, the top side S1a of the die 102a may be the side of the die 102a commonly referred to as the “active” or “front” side of the die 102a. In some embodiments, the top side S1a may include one or more transistors, logic gates, circuits, logic components, etc. (not illustrated in the figures). In some embodiments, the bottom surface S1b of the die 102a is commonly referred to as the “inactive” or “back” side of the die 102a.

In some embodiments, a bottom surface of the die 102b may be the side of the die 102b commonly referred to as the active or front side of the die 102b, and a bottom surface of the die 102c may be the side of the die 102c commonly referred to as the active or front side of the die 102c. Thus, for example, the active sides of the dies 102a and 102b are attached via the interconnect structures 110, 112, and 114, and also the active sides of the dies 102a and 102c are attached via the interconnect structures 110, 112, and 114. Thus, for example, the dies 102a and 102b are arranged in a face-to-face arrangement, and similarly, the dies 102a and 102c are also arranged in a face-to-face arrangement.

In some embodiments, a molding compound 120 is formed on at least a section of the package 100. The molding compound 120, for example, encapsulates at least a section of the dies 102a, 102b, and 102c, e.g., as illustrated in FIG. 1. In some embodiments, the molding compound 120 can be any suitable material, such as epoxy-based build-up substrate, other dielectric/organic materials, resins, epoxies, polymer adhesives, silicones, acrylics, polyimides, cyanate esters, thermoplastics, and/or thermosets.

In some embodiments, the die 102a comprises a plurality of interconnect components 116 and a plurality of through-silicon-vias (TSVs) 118. The interconnect components 116 and/or the TSVs 118 electrically interconnect various components of the dies 102a, 102b and/or 102c to respective ones of the interconnect structures 106. For example, the TSVs 118 connect various components of the dies 102a, 102b and/or 102c to the substrate 104 via the interconnect structure 106. In some embodiments, each interconnect structure 106 is formed on an end of a corresponding TSV 118, as illustrated in FIG. 1. Merely as an example, individual ones of the interconnect components 116 comprises traces, trenches, routing layers, ground planes, power planes, re-distribution layers (RDLs), and/or any other appropriate electrical routing features. Although a specific pattern of the interconnect components 116 are illustrated in FIG. 1, such a pattern is merely an example.

In some embodiments, the die 102a acts as an interposer between the dies 102b, 102c and the substrate 104. Accordingly, the die 102a is also referred to as an interposer die or a silicon interposer. In some embodiments, the interposer die 102a includes active circuit components, such as transistors, logic gates, circuits, and/or any appropriate components that are generally included in a semiconductor die.

In some embodiments, the substrate 104 comprises layers of interconnect components 122. The interconnect components 122, for example, can be traces, redistribution layers (RDLs), routing structures, routing layers, or other interconnect structures to interconnect various components of the substrate 104.

In some embodiments, the package 100 comprises a component 124. The component 124 can be, for example, any appropriate active or passive component, e.g., a capacitor, a resister, an inductor, a magnetic core inductor (MCI), a clock generation circuit, a voltage regulation circuit, or the like. In another example, the component 124 can also be a die, e.g., whose size is relatively small (e.g., compared to a size of the die 102a). In some embodiments, the component 124 can be mounted on a surface of the substrate 104, e.g., as illustrated in FIG. 1 (although in another embodiment, the component 124 may not be mounted on the substrate 104, as discussed herein later), and hence, is also referred to herein as a SMT component.

In some embodiments, the component 124 is mounted and attached to the substrate 104 via interconnect structures 126 and 128. The interconnect structures 128, for example, are bumps, bump pads, metal pillars (e.g., copper pillars), balls formed using metals, alloys, solderable material, or the like, and are attached to a bottom surface of the component 124. The interconnect structures 126, for example, are solder formed using metals, alloys, solderable material, or the like, and attach the interconnect structures 128 to the substrate 104.

In some embodiments, the component 124 is disposed at least in part in a recessed region 130 of the die 102a. For example, a portion of the inactive side of the die 102a (e.g., which corresponds to the bottom surface S1b) is removed or cut to form the recessed region 130, and the component 124 is disposed at least in part within this recessed region 130. In some embodiments, the recessed region 130 is formed in a portion of the die 102a that lacks the TSVs 118 and the interconnect components 116.

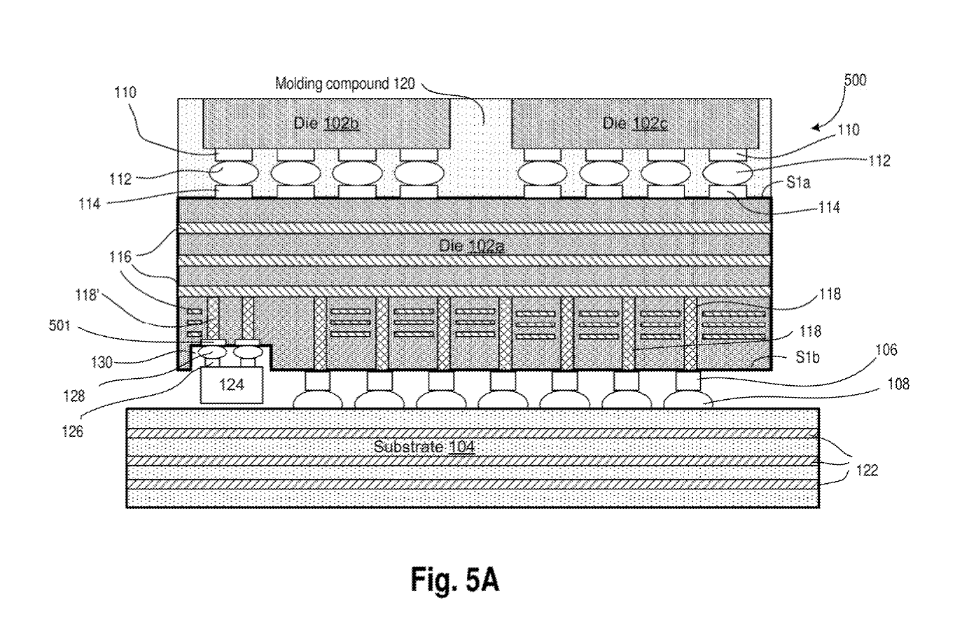

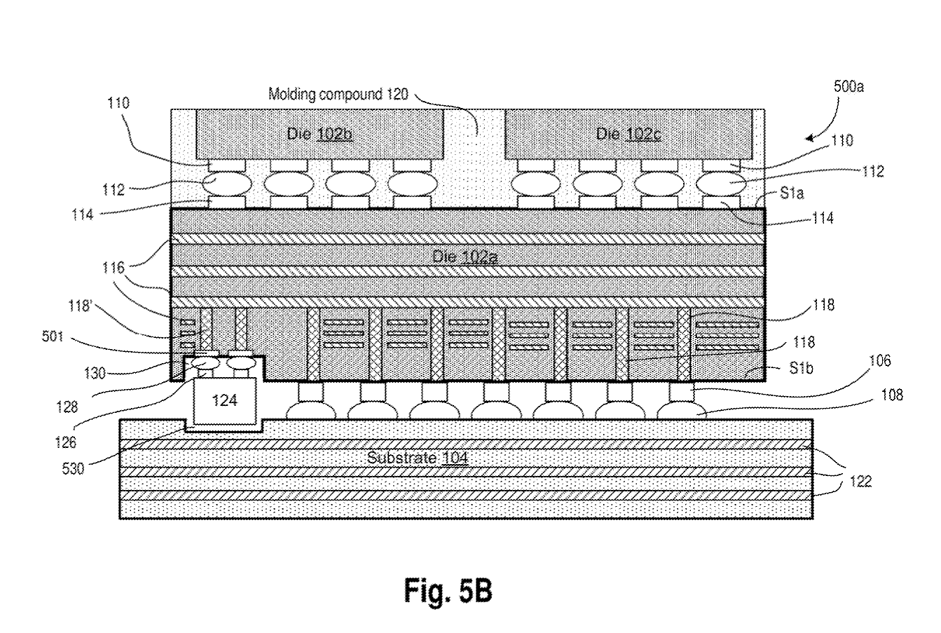

Although FIG. 1 illustrates the component 124 being disposed near a periphery of the die 102a (e.g., the recessed region 130 is formed near the periphery of the die 102a), the component 124 can be disposed in any region on the substrate 104. For example, the recessed region 130 may be formed in any appropriate position on the inactive side of the die 102 (e.g., on a section that lacks any TSVs 118 and interconnect components 116). In some other embodiments (e.g., as illustrated in FIG. 5A herein later), a recessed region can even be formed in a region of the die 102a that includes a TSV (e.g., via which the component 124 can be connected to various other components of the package).

Although a single component 124 is illustrated in FIG. 1 to be deposited in a single recessed region 130 of the die 102a, more than one such component can be respectively disposed in more than one recessed region of the die 102a. In another example and although not illustrated in FIG. 1, multiple such components can be disposed in a single recessed region (e.g., the recessed region 130) of the die 102a.

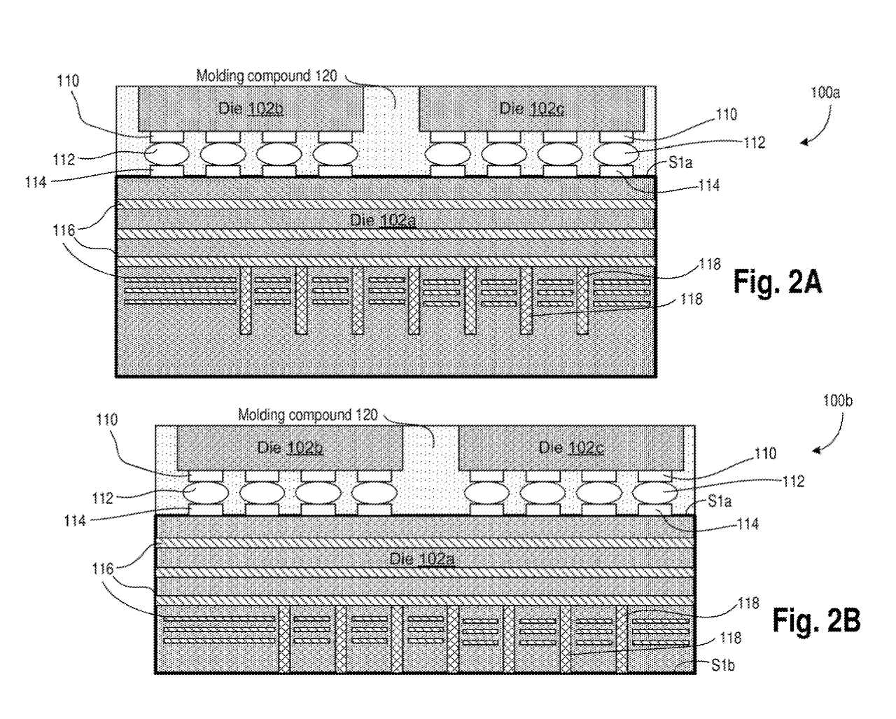

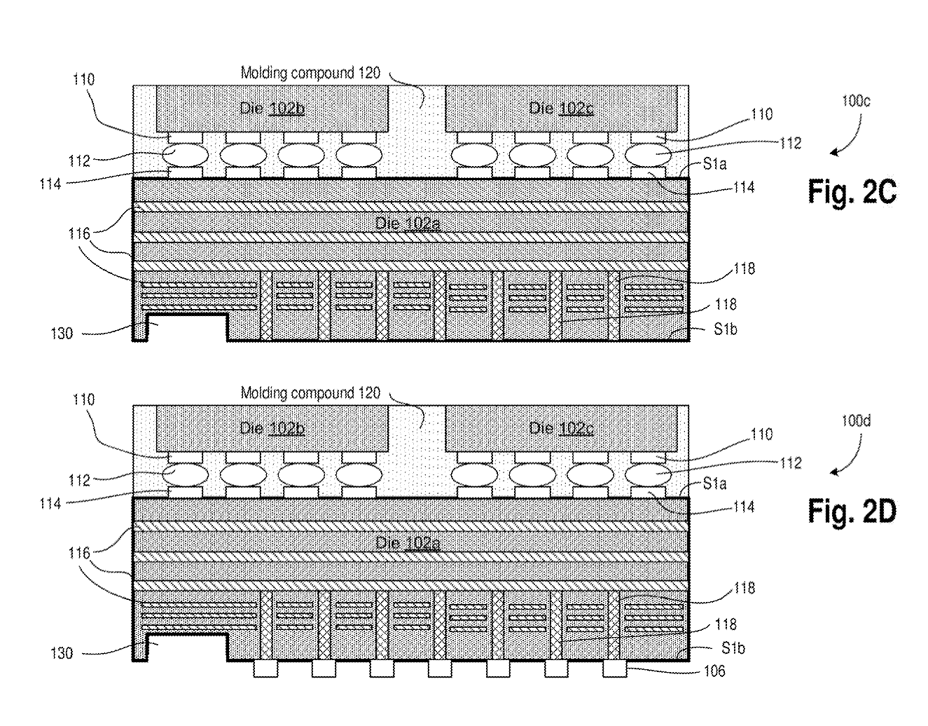

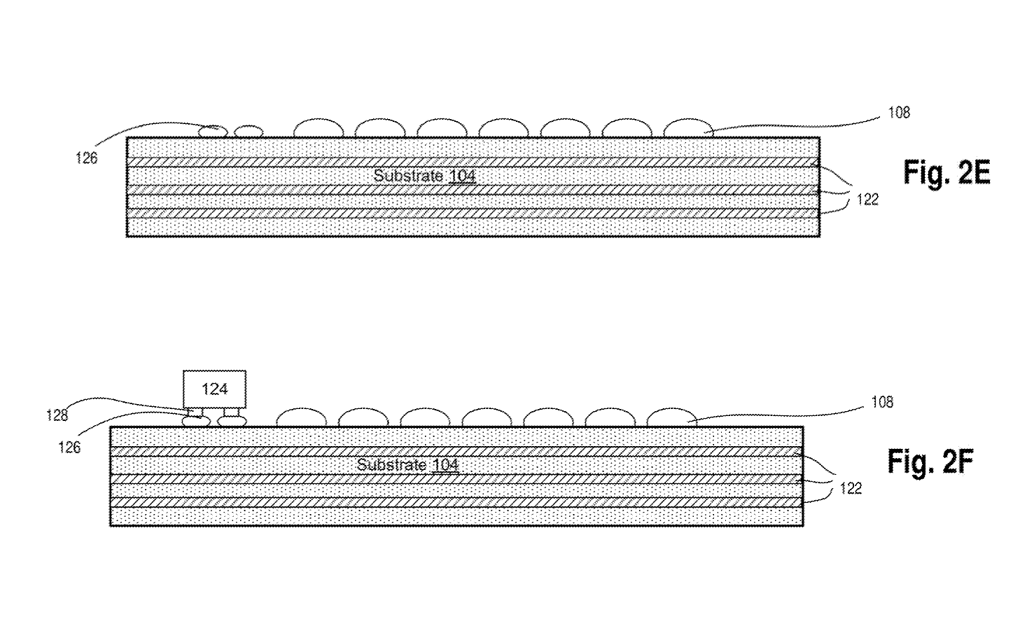

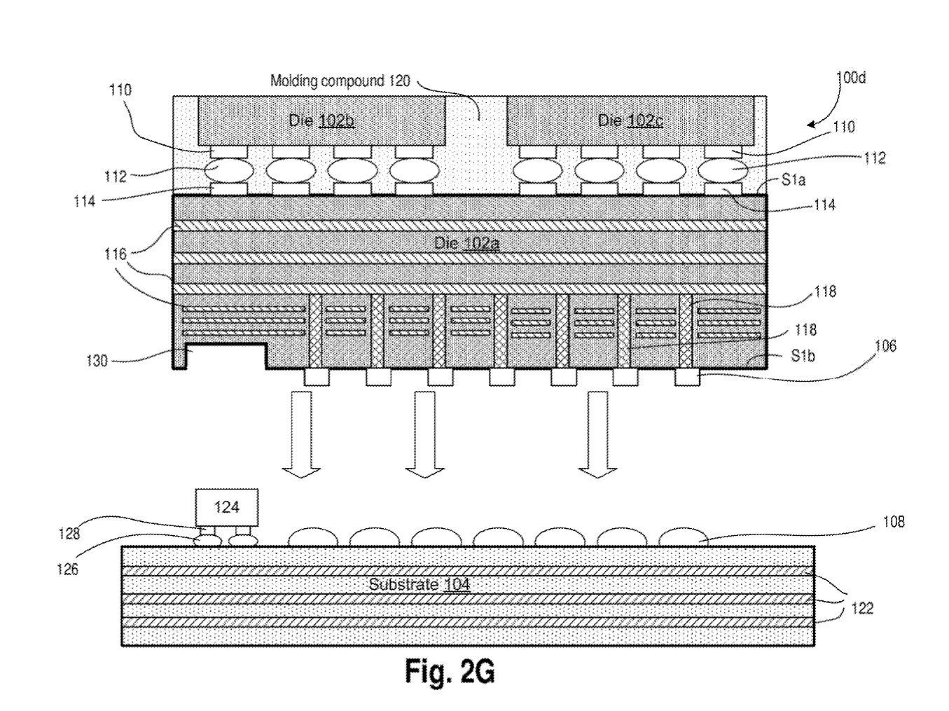

FIGS. 2A-2G illustrate a process of forming the package 100 of FIG. 1, where the package 100 comprises a recessed region in the die 102a in which the component 124 is mounted, according to some embodiments. Referring to FIG. 2A, a portion 100a of the package 100 comprises the dies 102a, 102b, and 102c, and the molding compound 120. The TSVs 118 are formed in a mid-section of the die 102a. For example, a bottom end of the TSVs 118 are not yet exposed through the bottom surface of the die 102a. The portion 100a of the package 100, as illustrated in FIG. 2A, can be formed using any appropriate technique for forming such a portion of a package.

In FIG. 2B, the bottom surface of the die 102a is removed, e.g., by using a chemical-mechanical planarization (CMP) process, by etching, by grinding, etc., e.g., until the bottom end of the TSVs 118 are revealed. For example, the bottom end of the TSVs 118 and the bottom surface S1b in FIG. 2B may be flush, e.g., so that the bottom end of the TSVs 118 are revealed through the bottom surface S1b of the die 102a.

In some embodiments, in FIG. 2C, a portion of the die 102a is removed to form a cavity or a recessed region 130 in the die 102a (e.g., thereby forming a partial package 100c), e.g., as discussed with respect to FIG. 1. The recessed region 130, for example, can be formed by etching (e.g., dry etching and/or wet etching) a section of the bottom surface S1b of the die 102a. In another example, the recessed region 130 can be formed by removing the section of the bottom surface S1b of the die 102a by any appropriate manner, e.g., by mechanically cutting the section, by a CMP process, by laser or mechanically drilling, and/or the like.

In some embodiments, in FIG. 2D, the plurality of interconnect structures 106 are formed on the bottom surface S1b of the die 102a, e.g., thereby forming a partial package 100d. For example, each interconnect structure 106 is attached to a corresponding one of a TSV 118.

In some embodiments, in FIG. 2E, the substrate 104 is formed, for example, using an appropriate technique for forming such a substrate. The substrate 104, for example, includes the interconnect components 122, and the interconnect structures 108 and 126. In FIG. 2F, in some embodiments, the component 124 is mounted on the substrate 104, e.g., via the interconnect structures 126 and 128. In an example, the component 124 can be attached to the interconnect structure 126 via an interconnect pad (not illustrated in FIG. 2F) or via copper bumps formed on the component 124 (e.g. the interconnect structures 126).

It is to be noted that the operations discussed with respect to FIGS. 2A-2D can be performed independent of the operations discussed with respect to FIGS. 2E-2F (for example, the operations of FIGS. 2A-2D can be performed prior to, at least in part parallel to, and/or subsequent to the operations discussed with respect to FIGS. 2E-2F).

In some embodiments, in FIG. 2G, the partial package 100d of FIG. 2D is mounted on the substrate 104 of FIG. 2F. In an example, the mounting of the partial package 100d of FIG. 2D on the substrate 104 of FIG. 2F, as illustrated in FIG. 2G, results in the package 100 of FIG. 1. In some embodiments, the partial package 100d of FIG. 2D is mounted on the substrate 104 of FIG. 2F such that the component 124 fits in the recessed region 130 of the die 102a.

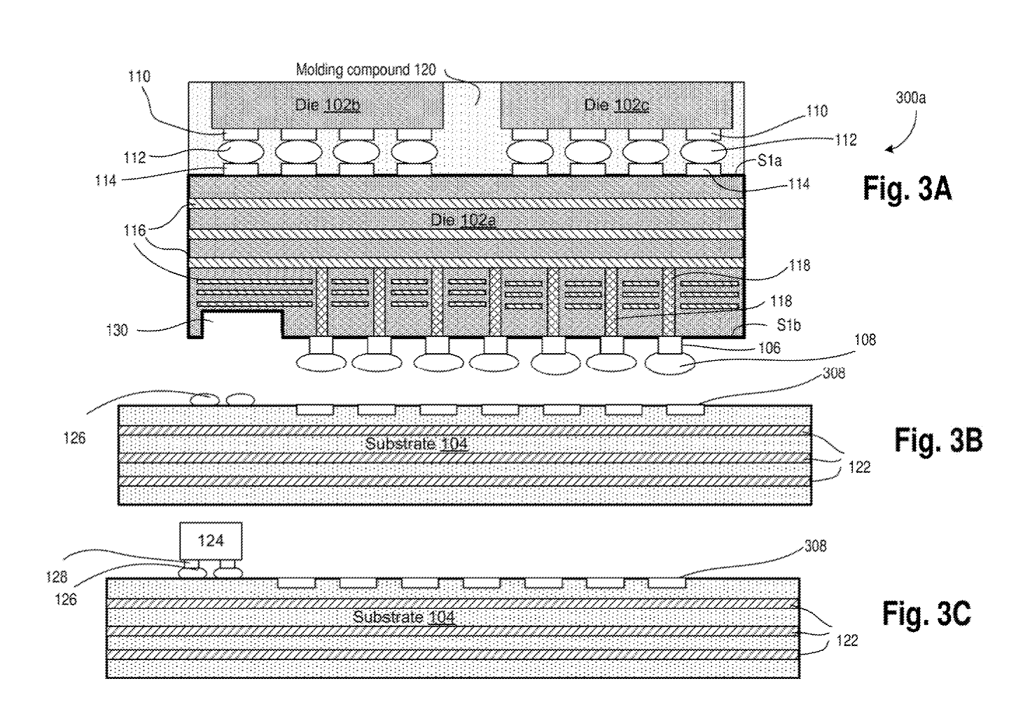

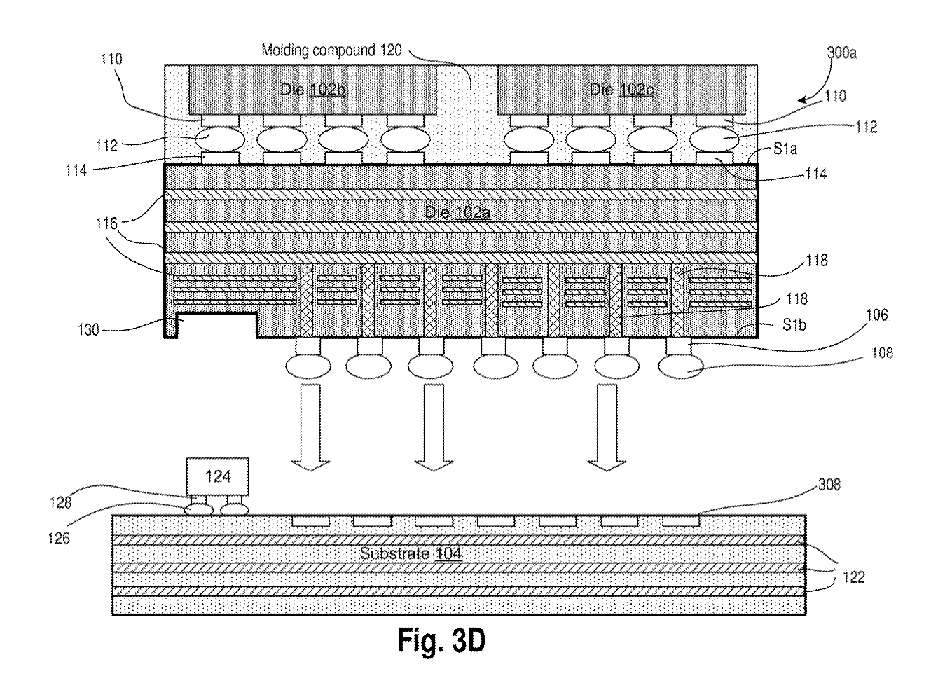

Several variations of the process described in FIGS. 2A-2G can be envisioned by those skilled in the art, e.g., based on the teachings of this disclosure. For example, as illustrated in FIG. 2E, the interconnect structures 108 are assumed to be initially deposited on the substrate (e.g., prior to the die 102a being mounted on the substrate 104). In another example, the interconnect structures 108 can be formed on the die 102a, as illustrated in FIGS. 3A-3D. FIGS. 3A-3D illustrate another process of forming the package 100 of FIG. 1, where the package 100 comprises a recessed region in the die 102a in which the component 124 is mounted, according to some embodiments.

FIG. 3A illustrates a partial package 300a, which is formed by depositing the interconnect structure 108 on the interconnect structures 106 of the partial package 100d of FIG. 2D. In some embodiments, because the interconnect structures 108 (which, for example, are solder) are formed on the die 102a, the process in FIG. 3A is also referred to as solder on die (SOD) process.

In some embodiments, in FIG. 3B, the substrate 104 is formed, for example, using an appropriate technique for forming such a substrate. The substrate 104, for example, includes the interconnect components 122, and the interconnect structures 126. In some embodiments (and although not illustrated in FIG. 1), the substrate 100 may comprise a plurality of interconnect pads 308. For example, when the partial package 300a is to be eventually mounted on the substrate 104, the interconnect structures 108 can be attached to the interconnect pads 308.

In FIG. 3C, in some embodiments, the component 124 is mounted on the substrate 104, e.g., via the interconnect structures 126 and 128. It is to be noted that the operations discussed with respect to FIG. 3A can be performed independent of the operations discussed with respect to FIGS. 3B-3C.

In some embodiments, in FIG. 3D, the partial package 300a of FIG. 3A is mounted on the substrate 104 of FIG. 3C. In an example, the mounting of the partial package 300a on the substrate 104 of FIG. 3C, as illustrated in FIG. 3D, results in the package 100 of FIG. 1. In some embodiments, the partial package 300a of FIG. 3A is mounted on the substrate 104 of FIG. 3C such that the component 124 fits in the recessed region 130 of the die 102a, and each interconnect structure 108 is attached to a corresponding interconnect pad 308.

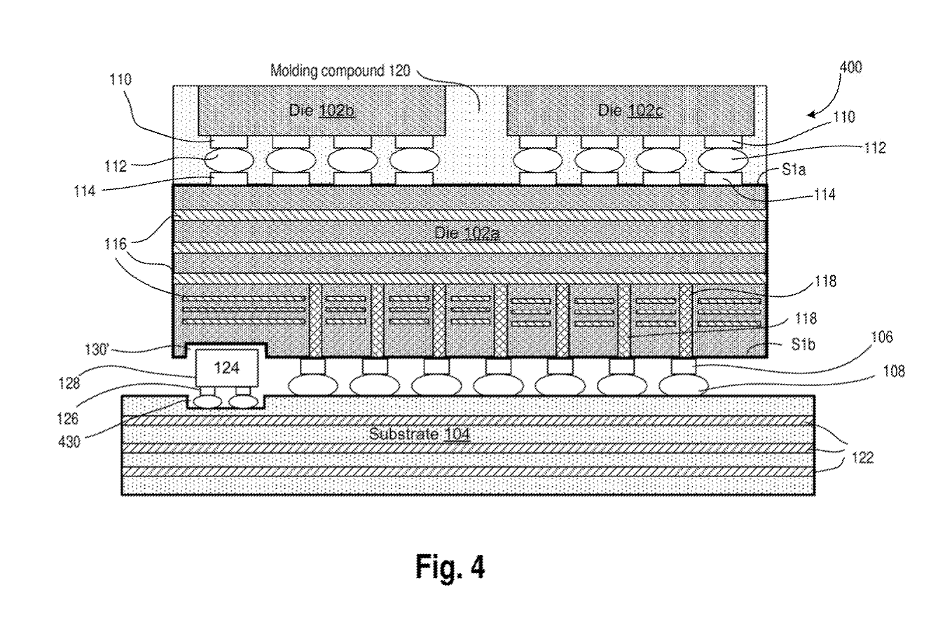

In FIGS. 1-3D, the component 124 is mounted on the substrate 104. In some embodiments, at least a part of the substrate 104 can also be recessed, and the component 124 can at least in part be within the recessed region of the substrate 104. For example, FIG. 4 illustrates a cross-sectional view of a semiconductor package 400 (henceforth also referred to as “package 400”) comprising a stacked plurality of dies, wherein a first die of the stacked plurality of dies and a substrate is selectively recessed to accommodate a component 124, according to some embodiments. The package 400 is similar to the package 100 of FIG. 1, and hence, similar components are labeled similarly. However, unlike FIG. 1, in addition to a recessed region 130′ in the die 102a, another recessed region 430 is formed on the substrate 104, e.g., where the component 124 is to be mounted. The component 124 fits within the two recessed regions 130′ and 430. In some examples, because the recessed region 430 provides some space for the component 124, the recessed region 130′ of the package 400 can be relatively small compared to the recessed region 130 of the package 100.

Several other variations of the package 100 is also possible. For example, the component 124 in the package 100 of FIG. 1 is mounted on the substrate 124, and is electrically connected to the substrate 124. However, in other embodiments, the component 124 can be electrically connected to, and/or mounted on the die 102a. For example, FIG. 5A illustrates a cross-sectional view of a semiconductor package 500 (henceforth also referred to as “package 500”) comprising a stacked plurality of dies, wherein a first die of the stacked plurality of dies is selectively recessed to accommodate a component 124 that is electrically coupled to the first die, according to some embodiments. The package 500 comprises components that are at least in part similar to the components of the package 100 of FIG. 1, and hence, these components in FIGS. 1 and 5 are labeled using similar labels. However, unlike the package 100, in the package 500, the component 124 is mounted on, and attached to the die 102a. The component 124 is mounted within the recessed region 130. The component 124 is mounted on the die 102a using, for example, the interconnect structures 126 and 128.

In some embodiments, in the package 500, interconnect pads 501 are formed in the top surface of the recessed region 130, and the interconnect structures 128 are attached to the interconnect pads 501. In some embodiments, to facilitate electrical connection between the component 124 and other components of the package 500, TSVs 118′ through the die 102a are connected to the interconnect pads 501.

FIG. 5B illustrates a cross-sectional view of a semiconductor package comprising a stacked plurality of dies, wherein a first die of the stacked plurality of dies and a substrate are selectively recessed to accommodate a component that is electrically coupled to the first die, according to some embodiments. A package 500b illustrated in FIG. 5B is substantially similar to the package 500 of FIG. 5A. However, in FIG. 5B, in addition to the recessed region 130, another recessed region 530 is formed in the substrate 104 (e.g., similar to the recessed region 430 of FIG. 4). The component 124 is disposed at least in part within the two recessed regions 130 and 530. FIG. 5B is self-explanatory in view of FIG. 5A, and hence, will not be discussed in further details herein.

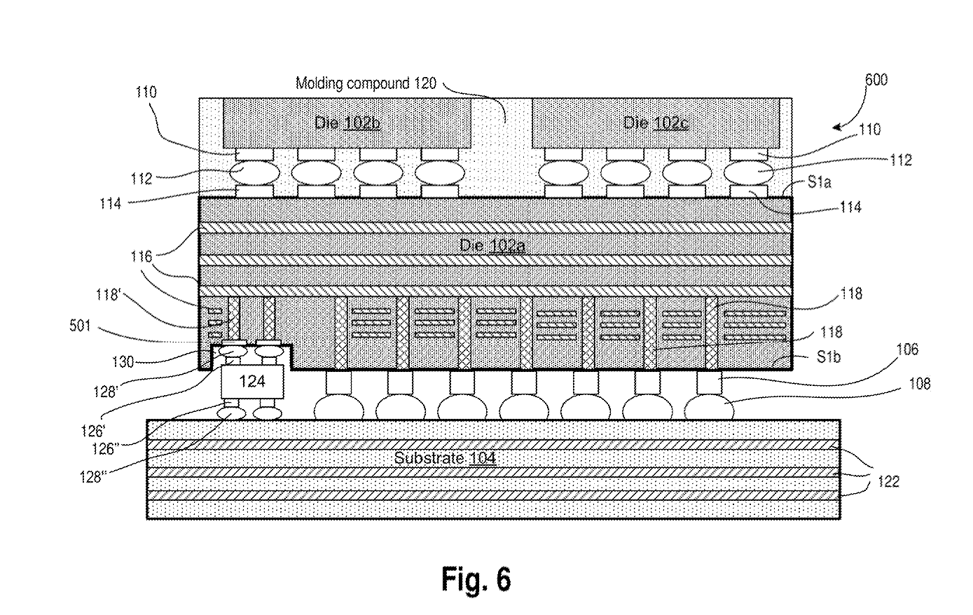

FIG. 6 illustrates a cross-sectional view of a semiconductor package 600 (henceforth also referred to as “package 600”) comprising a stacked plurality of dies, wherein a first die of the stacked plurality of dies is selectively recessed to accommodate a component 124 that is electrically coupled to the first die and to a substrate, according to some embodiments. The package 600 comprises components that are at least in part similar to the components of the package 100 of FIG. 1, and hence, these components in FIGS. 1 and 6 are labeled using similar labels. In some embodiments, unlike the package 100, in the package 500, the component 124 is attached to both the die 102a and the substrate 104. The component 124 is mounted within the recessed region 130. The component 124 is electrically connected on the die 102a using, for example, the interconnect structures 126′ and 128′, and is electrically connected on the substrate 104 using, for example, the interconnect structures 126″ and 128″.

Merely as an example, the component 124 may comprise a capacitor, and one end of the capacitor 124 can be electrically coupled to the die 102a, and another end to the substrate 104. In yet another example, the component 124 is a voltage regulator, and the voltage regulator supplies a voltage to both the die 102a and the substrate 104 (e.g., via the respective connections illustrated in FIG. 6).

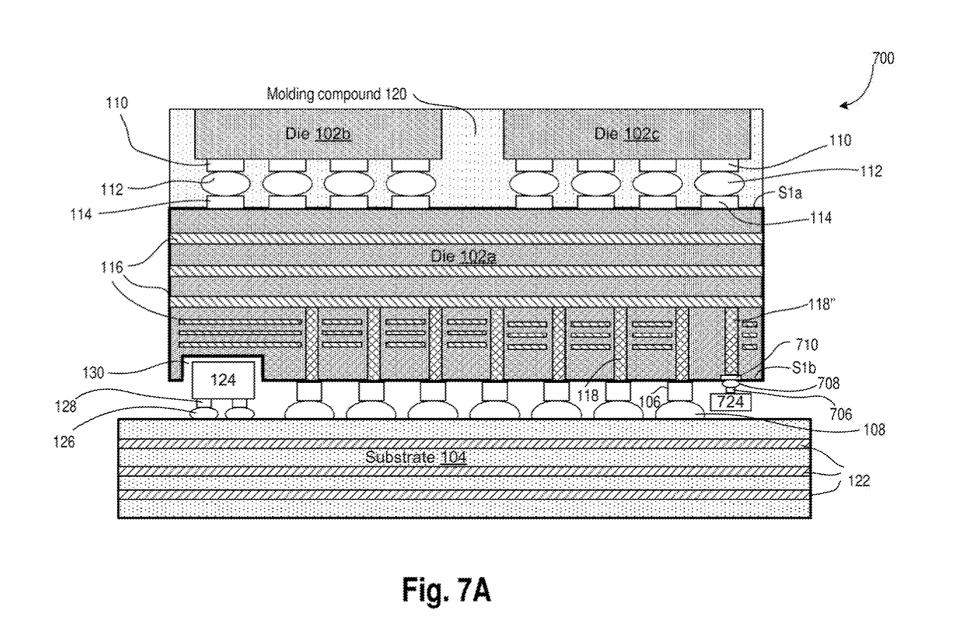

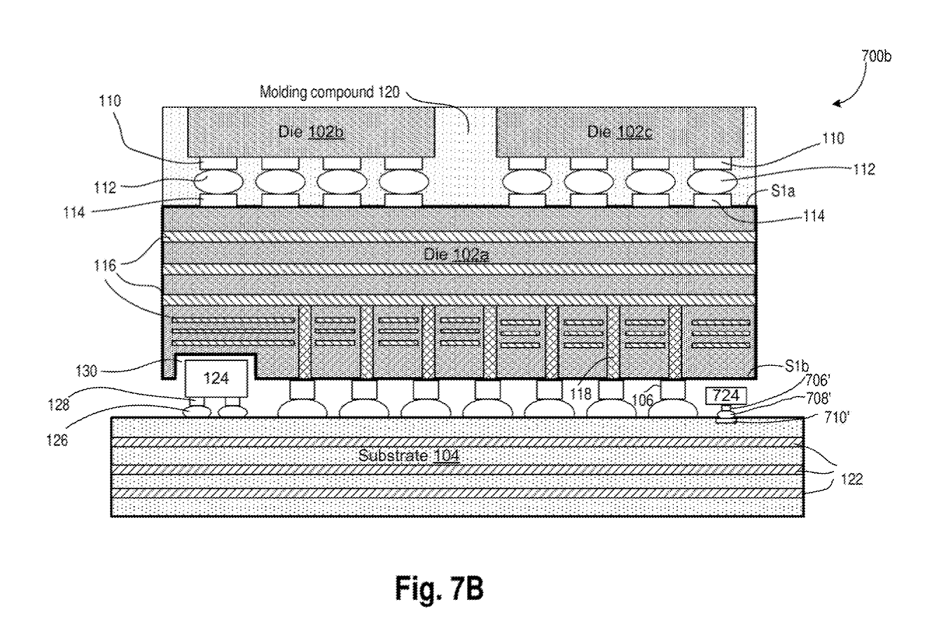

FIG. 7A illustrates a cross-sectional view of a semiconductor package 700 (henceforth also referred to as “package 700”) comprising a stacked plurality of dies, wherein a first die (e.g., the die 102a) of the stacked plurality of dies is selectively recessed to accommodate a first component 124, and wherein a second component is disposed between an un-recessed region of the first die and the substrate, according to some embodiments. The package 700 comprises components that are at least in part similar to the components of the package 100 of FIG. 1, and hence, these components in FIGS. 1 and 7A are labeled using similar labels. In some embodiments, in addition to the component 124, another component 724 is attached to the bottom surface S1b of the die 102a (e.g., in the space between the die 102a and the substrate 104). The component 724 is mounted on the die 102a via, for example, interconnect structures 706 and 708, and interconnect pads 710. The interconnect structures 706, for example, are bumps, bump pads, metal pillars (e.g., copper pillars), balls formed using metals, alloys, solderable material, or the like, and are attached to the bottom surface of the die 102a. The interconnect structures 708, for example, are solder formed using metals, alloys, solderable material, or the like, and attach the interconnect structures 706 to the die 102a. The component 724 comprises, for example, any active and/or passive component, e.g., a capacitor, an inductor, a resistor, a clock generator, a voltage regulator, etc. Although not illustrated in FIG. 7A, in some embodiments, the component 724 can be attached to the die 102a using ACF, ACP, and/or any adhesive based interconnect (e.g., instead of the interconnect structures 706 and 708).

FIG. 7B illustrates a cross-sectional view of a semiconductor package comprising a stacked plurality of dies, wherein a first die of the stacked plurality of dies is selectively recessed to accommodate a first component, and wherein a second component is disposed between an un-recessed region of the first die and the substrate and attached to the substrate, according to some embodiments. A package 700b illustrated in FIG. 7B is substantially similar to the package 700 of FIG. 7A. However, in FIG. 7B, the component 724 is attached to the substrate 104, e.g., using interconnect structures 706′ and 708′, and interconnect pads 710′. FIG. 7B is self-explanatory in view of FIG. 7A, and hence, will not be discussed in further details herein.

Although FIGS. 7A-7B illustrate the component 724 being attached to either the die 102a or the substrate 104, in some embodiments (and although not illustrated in the figures), the component 724 can be attached to both the die 102a and the substrate 104, e.g., via respective interconnect structures.

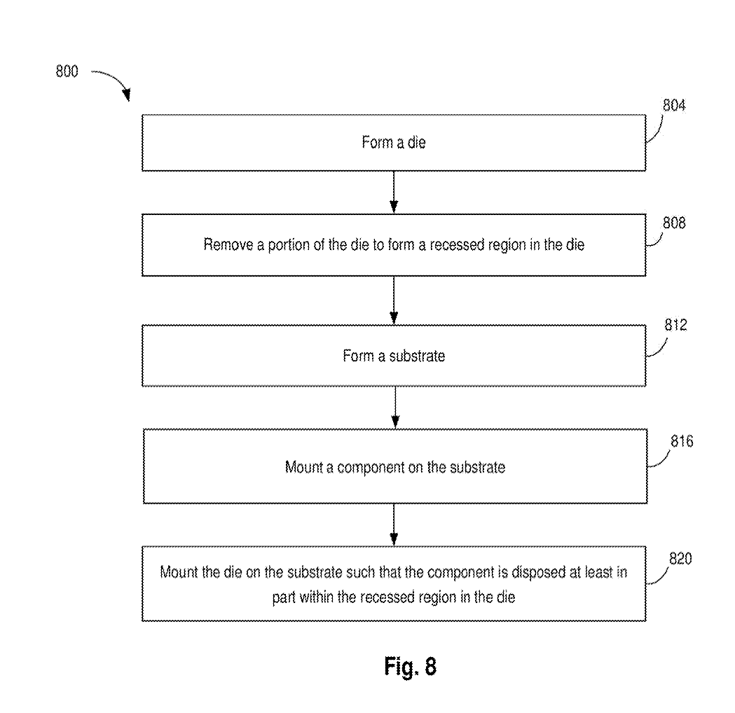

FIG. 8 illustrates a flowchart depicting a method 800 for disposing a component (e.g., the component 124 of FIG. 1) in a recessed region of a die (e.g., the recessed region 130 of the die 102a of FIG. 1), where the die is part of a stack of multiple dies (e.g., dies 102a, 102b, 102c), according to some embodiments. At 804, the die is formed, e.g., as discussed with respect to FIGS. 2A-2B. At 808, a portion of the die is removed to form the recessed region in the die, e.g., as discussed with respect to FIG. 2C.

At 812, a substrate (e.g., the substrate 104 of FIG. 1) is formed, e.g., as discussed with respect to FIG. 2E. In some embodiments, the substrate can be formed without any recessed region, e.g., as discussed with respect to FIG. 1. In some other embodiments, the substrate can be formed with a recessed region (e.g., recessed region 530), e.g., as discussed with respect to FIG. 5B.

At 816, the component is mounted on the substrate, e.g., as discussed with respect to FIG. 2F. At 820, the die is mounted on the substrate e.g., as discussed with respect to FIG. 2G. In some embodiments, the die is mounted such that the component is disposed at least in part within the recessed region in the die. In some embodiments where the substrate also has a recessed region, the die is mounted such that the component is disposed at least in part within the recessed region in the substrate, e.g., as illustrated in FIG. 5B.

Although FIG. 8 illustrates various operations of the method 800 in a particular order, the operations can be performed in a different order as well. Merely as an example, the formation of the substrate and mounting the component on the substrate, as discussed in blocks 812 and 816, can be performed at least in part in parallel to, or prior to the operations discussed with respect to the blocks 804 and 808 of the method 800. Some of the blocks and/or operations listed in FIG. 8 may be optional in accordance with certain embodiments. The numbering of the blocks presented is for the sake of clarity and is not intended to prescribe an order of operations in which the various blocks must occur.

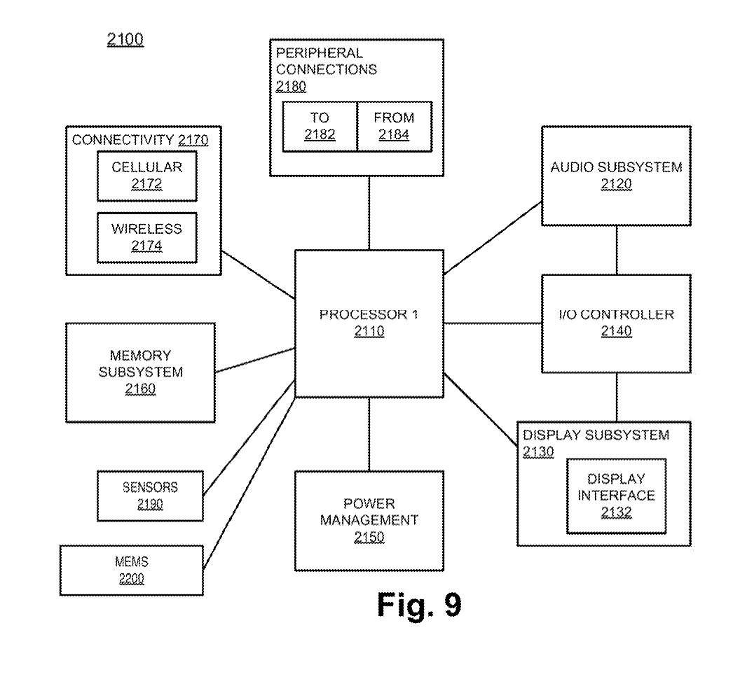

FIG. 9 illustrates a computing device 2100, a smart device, a computing device or a computer system or a SoC (System-on-Chip) 2100, in which a second die is stacked on a first die in a flip chip configuration, where an inactive side of the first die is recessed and a component is disposed at least in part on the recessed region in the first die, according to some embodiments. It is pointed out that those elements of FIG. 9 having the same reference numbers (or names) as the elements of any other figure can operate or function in any manner similar to that described, but are not limited to such.

Here, the various blocks forming the computing device 2100 may be packaged as a stack of dies with at least one recessed region in which a component is disposed, e.g., as discussed with respect to FIGS. 1-7 and as discussed in this disclosure. Here, one or more blocks forming the computing device 2100 may be packaged, for example, in one or more of the packages illustrated in one or more of FIGS. 1-7.

In some embodiments, computing device 2100 represents an appropriate computing device, such as a computing tablet, a mobile phone or smart-phone, a laptop, a desktop, an IOT device, a server, a set-top box, a wireless-enabled e-reader, or the like. It will be understood that certain components are shown generally, and not all components of such a device are shown in computing device 2100.

In some embodiments, computing device 2100 includes a first processor 2110. The various embodiments of the present disclosure may also comprise a network interface within 2170 such as a wireless interface so that a system embodiment may be incorporated into a wireless device, for example, cell phone or personal digital assistant.

In one embodiment, processor 2110 can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O (input/output) with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, SOC 2100 includes sensors 2190 (e.g., temperature sensors, accelerometers, gyroscopes, etc.). In some embodiments, SOC 2100 includes one or more MEMs 2200 (Microelectromechanical systems).

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following example clauses pertain to further embodiments. Specifics in the example clauses may be used anywhere in one or more embodiments. All optional features of the apparatus described herein may also be implemented with respect to a method or process.

Clause 1. An apparatus comprising: a substrate; a die having a first side and a second side, wherein the die is mounted on the substrate such that the first side of the die faces the substrate, and wherein at least a portion of the first side of the die is removed to form a recess in the die; and a component, wherein at least a part of the component is disposed within the recess in the first die.

Clause 2. The apparatus of clause 1, wherein the component is mounted on the substrate and is electrically coupled to the substrate.

Clause 3. The apparatus of clause 1, wherein the component is mounted on the die and is electrically coupled to the die.

Clause 4. The apparatus of any of clauses 1-3, wherein the component is (i) electrically coupled to the die through a first interconnect structure and (ii) electrically coupled to the substrate through a second interconnect structure.

Clause 5. The apparatus of any of clauses 1-3, wherein the first side of the die is an inactive side of the die, and wherein the second side of the die is an active side of the die.

Clause 6. The apparatus of any of clauses 1-3, wherein the die is a first die, and wherein the apparatus further comprises: a second die mounted on the second side of the first die.

Clause 7. The apparatus of clause 6, further comprising: a third die mounted on the second side of the first die.

Clause 8. The apparatus of any of clauses 6-7, further comprising: a through silicon via (TSV) formed in the first die, wherein the second die is electrically coupled to the substrate through the TSV formed in the first die.

Clause 9. The apparatus of any of clauses 1-8, wherein the component is a first component, and wherein the apparatus further comprises: a second component, wherein at least another portion of the first side of the die is un-recessed, and wherein the second component is attached to the at least another portion of the first side of the die such that the second component is between the die and the substrate.

Clause 10. A semiconductor package comprising: the apparatus of any of clauses 1-9; and molding compound that at least in part encapsulates the die.

Clause 11. A semiconductor package comprising: a substrate; a plurality of dies mounted on the substrate, the plurality of dies comprising a first die mounted on the substrate; a recessed region formed in the first die; and a component disposed at least in part within the recessed region.

Clause 12. The semiconductor package of clause 11, wherein: the component is electrically coupled to the substrate via one or more interconnect structures.

Clause 13. The semiconductor package of clause 11, wherein: the component is electrically coupled to the first die via one or more interconnect structures.

Clause 14. The semiconductor package of any of clauses 11-13, further comprising: molding compound that at least in part encapsulates the plurality of dies.

Clause 15. The semiconductor package of any of clauses 11-14, wherein: the recessed region is formed in an inactive side of the first die.

Clause 16. The semiconductor package of clause 15, wherein: the plurality of dies comprises a second die mounted on an active side of the first die.

Clause 17. The semiconductor package of any of clauses 11-16, wherein the component is a first component, and wherein the semiconductor package further comprises: a second component disposed between an un-recessed region of the first die and the substrate.

Clause 18. A method comprising: forming a first die; removing a portion of the first die to form a recessed region in the first die; forming a substrate; mounting a component on the substrate; and mounting the first die on the substrate such that the component is disposed at least in part within the recessed region in the first die.

Clause 19. The method of clause 18, wherein the recessed region is formed on a first side of the first die, and wherein the method further comprises: mounting a second die on a second side of the first die in a flip-chip configuration.

Clause 20. The method of clause 19, wherein the first side of the first die is an inactive side of the first die, and the second side of the first die is an active side of the first die.

Clause 21. The method of any of clauses 19-20, further comprising: forming a through silicon via (TSV) in the first die; and electrically coupling the second die to the substrate through the TSV.

Clause 22. The method of any of clauses 18-21, further comprising: attaching another component to an un-recessed region of the first die such that the another component is between the first die and the substrate.

Clause 23. The method of any of clauses 18-21, further comprising: electrically coupling the component to the first die through a first interconnect structure.

Clause 24. The method of any of clause 23, further comprising: electrically coupling the component to the substrate through a second interconnect structure.

Clause 25. An apparatus comprising: means for performing the method of any of clauses 18-24.

Clause 26. An apparatus comprising: means for forming a first die; means for removing a portion of the first die to form a recessed region in the first die; means for forming a substrate; means for mounting a component on the substrate; and means for mounting the first die on the substrate such that the component is disposed at least in part within the recessed region in the first die.

Clause 27. The apparatus of clause 26, wherein the recessed region is formed on a first side of the first die, and wherein the apparatus further comprises: means for mounting a second die on a second side of the first die in a flip-chip configuration.

Clause 28. The apparatus of clause 27, wherein the first side of the first die is an inactive side of the first die, and the second side of the first die is an active side of the first die.

Clause 29. The apparatus of any of clauses 27-28, further comprising: means for forming a through silicon via (TSV) in the first die; and means for electrically coupling the second die to the substrate through the TSV.

Clause 30. The apparatus of any of clauses 26-30, further comprising: means for attaching another component to an un-recessed region of the first die such that the another component is between the first die and the substrate.

Clause 31. The apparatus of any of clauses 26-31, further comprising: means for electrically coupling the component to the first die through a first interconnect structure.

Clause 32. The apparatus of clause 31, further comprising: means for electrically coupling the component to the substrate through a second interconnect structure.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-25. (canceled)

26. An apparatus comprising:
a substrate;
a die having a first side and a second side, wherein the die is on the substrate such that the first side of the die faces the substrate, and wherein at least a portion of the first side of the die is removed to form a recess in the die; and
a component, wherein at least a part of the component is within the recess in the first die.

27. The apparatus of claim 26, wherein the component is mounted on the substrate and is electrically coupled to the substrate.

28. The apparatus of claim 26, wherein the component is mounted on the die and is electrically coupled to the die.

29. The apparatus of claim 26, wherein the component is:
electrically coupled to the die through a first interconnect structure; and
electrically coupled to the substrate through a second interconnect structure.

30. The apparatus of claim 26, wherein the first side of the die comprises an inactive side of the die, and wherein the second side of the die comprises an active side of the die.

31. The apparatus of claim 26, wherein the die is a first die, and wherein the apparatus further comprises:
a second die on the second side of the first die.

32. The apparatus of claim 31, further comprising:
a third die on the second side of the first die.

33. The apparatus of claim 31, further comprising:
a through silicon via (TSV) in the first die, wherein the second die is electrically coupled to the substrate through the TSV.

34. The apparatus of claim 26, wherein the component is a first component, and wherein the apparatus further comprises:
a second component, wherein at least another portion of the first side of the die is un-recessed, and wherein the second component is attached to the at least another portion of the first side of the die such that the second component is between the die and the substrate.

35. A semiconductor package comprising:
a substrate;
a plurality of dies on the substrate, the plurality of dies comprising a first die on the substrate;
a recessed region formed in the first die; and
a component at least in part within the recessed region.

36. The semiconductor package of claim 35, wherein:
the component is electrically coupled to the substrate via one or more interconnect structures.

37. The semiconductor package of claim 35, wherein:
the component is electrically coupled to the first die via one or more interconnect structures.

38. The semiconductor package of claim 35, further comprising:
a compound that at least in part encapsulates the plurality of dies, wherein the compound comprises mold material.

39. The semiconductor package of claim 35, wherein:
the recessed region is in an inactive side of the first die.

40. The semiconductor package of claim 39, wherein:
the plurality of dies comprises a second die on an active side of the first die.

41. The semiconductor package of claim 39, wherein the component is a first component, and wherein the semiconductor package further comprises:
a second component between an un-recessed region of the first die and the substrate.

42. A method comprising:
forming a first die;
removing a portion of the first die to form a recessed region in the first die;
forming a substrate;
mounting a component on the substrate; and
mounting the first die on the substrate such that the component is disposed at least in part within the recessed region in the first die.

43. The method of claim 42, wherein the recessed region is formed on a first side of the first die, and wherein the method further comprises:
mounting a second die on a second side of the first die in a flip-chip configuration.

44. The method of claim 43, wherein the first side of the first die is an inactive side of the first die, and the second side of the first die is an active side of the first die.

45. The method of claim 42, further comprising:
attaching another component to an un-recessed region of the first die such that the another component is between the first die and the substrate.
